(19) United States
(12) Patent Application Publication
(10) Pub. No.: US 2015/0325538 A1
(43) Pub. Date: Nov. 12, 2015

(54) SEMICONDUCTOR DEVICE AND METHOD FOR PRODUCING SEMICONDUCTOR DEVICE

(71) Applicant: TOYOTA JIDOSHA KABUSHIKI KAISHA, Toyota-shi (JP)

(72) Inventors: Kazuya ASAOKA, Seto-shi (JP); Norio FUJITSUKA, Nagakute-shi (JP); Takashi OZAKI, Nagakute-shi (JP); Kenichi AO, Tokai-shi (JP)

(21) Appl. No.: 14/699,411

(22) Filed: Apr. 29, 2015

(30) Foreign Application Priority Data
May 12, 2014 (JP) 2014-098753

(51) Int. Cl. H01L 23/00; H01L 23/31; H01L 23/48; H01L 21/302

(52) U.S. Cl. CPC H01L 24/08; H01L 24/03; H01L 21/302; H01L 23/3157; H01L 24/89; H01L 23/481; H01L 2224/0331; H01L 2224/0311; H01L 2224/08111; H01L 2224/04026; H01L 2224/05571; H01L 2224/08146; H01L 2224/80001

(57) ABSTRACT

The method for producing a semiconductor device includes: forming an opening in an area of at least one of the complementary metal-oxide semiconductor wafer that includes a first part and the other semiconductor wafer that includes a second part, the opening terminating within the area and not penetrating through the area, the area including corresponding one of the first part and the second part and an outer peripheral part of the corresponding one of the first part and the second part; forming a conduction hole within the first part, the conduction hole communicating with a metallic material in the complementary metal-oxide semiconductor wafer; arranging a first joining material inside the conduction hole and on the first part, and a second joining material on the second part; and joining the arranged first joining material and the arranged second joining material.

### CROSS-REFERENCE TO RELATED APPLICATION

This application claims priority to Japanese Patent Application No. 2014-098753, filed on May 12, 2014, the contents of which are hereby incorporated by reference into the present application.

### TECHNICAL FIELD

The present specification relates to a semiconductor device and a method for producing a semiconductor device.

### DESCRIPTION OF RELATED ART

Japanese patent application publication No. 2008-533743 discloses a method for forming a connection between a first substrate and a second substrate. First, a joining structure including metal is formed on each of the first substrate and the second substrate. Then, the joining structure on the first substrate is joined to the joining structure on the second substrate to form the connection.

In the method for forming the connection according to the above patent literature 1, the metal included in the two joining structures is dissolved at the time of joining. Hence, gravity and a force in a vertical direction caused by the joining are applied to the metal, and thus the dissolved metal is easily spread in a horizontal direction. Consequently, the following problem is highly likely to occur: the metal makes contact with a part where the contact is not to be made or the metal flows out of the substrate and the like. In particular, when a plurality of parts where a junction is formed are present, and the space between the joining parts is narrow, the joining parts are highly likely to contact with each other.

### BRIEF SUMMARY OF INVENTION

The present specification provides a technology in which when two semiconductor wafers are joined, the spreading of a joining material in a horizontal direction is reduced.

One aspect disclosed in the present specification may be a method for producing a semiconductor device that comprises a complementary metal-oxide semiconductor wafer and another semiconductor wafer. The complementary metal-oxide semiconductor wafer may include a protective coating. The method may comprise: forming an opening in an area of at least one of the complementary metal-oxide semiconductor wafer that includes a first part and the other semiconductor wafer that includes a second part, the opening terminating within the area and not penetrating through the area, the area including corresponding one of the first part and the second part and an outer peripheral part of the corresponding one of the first part and the second part, the first part including a part of a surface of the complementary metal-oxide semiconductor wafer on which the protective coating is located and a part of the complementary metal-oxide semiconductor wafer continuing inward from the part of the surface, the second part including a part of a surface of the other semiconductor wafer and a part of the other semiconductor wafer continuing inward from the part of the surface; forming a conduction hole within the first part, the conduction hole communicating with a metallic material in the complementary metal-oxide semiconductor wafer; arranging a first joining material inside the conduction hole and on the first part, and a second joining material on the second part; and joining the arranged first joining material and the arranged second joining material.

In the configuration described above, in the forming of the opening, the opening is formed in the complementary metal-oxide semiconductor wafer and/or the semiconductor wafer, and thus a step is formed in the surfaces within and outside the opening. Hence, even if the first joining material and the second joining material flow in the horizontal direction in the joining, they are unlikely to flow to the outside of the opening. That is, the spreading of the first joining material and the second joining material in the horizontal direction can be reduced.

Another aspect disclosed in the present specification may be a semiconductor device comprising: a complementary metal-oxide semiconductor wafer; and another semiconductor wafer, wherein the complementary metal-oxide semiconductor wafer comprises: a protective coating located on a surface of the complementary metal-oxide semiconductor wafer; a metallic material located in the complementary metal-oxide semiconductor wafer; a conduction hole communicating with the metallic material from a first surface being a surface on which the protective coating is located; and a first joining material located in the conduction hole and on the first surface, the other semiconductor wafer comprises a second joining material located on a second surface of the other semiconductor wafer and joined to the first joining material, and the semiconductor device comprises an opening on at least one of the first surface of the complementary metal-oxide semiconductor and the second surface of the other semiconductor, the opening terminating within and not penetrating through the corresponding one of the complementary metal-oxide semiconductor wafer and the other semiconductor wafer, wherein the first joining material and the second joining material fill at least a part of the opening is located on the at least one of the first surface and the second surface. The above semiconductor device corresponds to a semiconductor device produced by the above method. That is, with the configuration described above, the spreading of the first joining material and the second joining material in the horizontal direction can be also reduced.

### BRIEF DESCRIPTION OF THE DRAWINGS

FIGS. 1 to 3 are cross-sectional views for illustrating a process of forming an opening in a first embodiment.

FIG. 4 is a cross-sectional view for illustrating a process of forming a conduction hole in the first embodiment.

FIG. 5 is a cross-sectional view for illustrating an arranging process in the first embodiment.

FIG. 6 is a cross-sectional view for illustrating the arranging process in the first embodiment.

FIG. 7 is a cross-sectional view for illustrating a joining process in the first embodiment.

FIG. 8 is a top view of a semiconductor device including sealing.

FIG. 9 is a cross-sectional view sectioned along dashed line IX of FIG. 8.

FIGS. 10 to 12 are cross-sectional views for illustrating a process of forming an opening in a second embodiment.

FIG. 13 is a cross-sectional view for illustrating a process of forming a conduction hole in the second embodiment.

FIG. 14 is a cross-sectional view for illustrating an arranging process in the second embodiment.

FIG. 15 is a cross-sectional view for illustrating the arranging process in the second embodiment.

FIG. 16 is a cross-sectional view for illustrating a joining process in the second embodiment.

FIGS. 17 to 19 are cross-sectional views for illustrating processes of forming an opening and forming a groove in a third embodiment.

FIG. 20 is a cross-sectional view for illustrating a process of forming a conduction hole in the third embodiment.

FIG. 21 is a cross-sectional view for illustrating an arranging process in the third embodiment.

FIGS. 22 and 23 are cross-sectional views for illustrating a joining process in the third embodiment.

FIG. 24 is a cross-sectional view for illustrating a process of forming a groove in a fourth embodiment.

FIG. 25 is a cross-sectional view for illustrating a joining process in the fourth embodiment.

FIG. 26 is a cross-sectional view for illustrating a process of forming an opening in a fifth embodiment.

FIG. 27 is a cross-sectional view for illustrating a joining process in the fifth embodiment.

FIG. 28 is a cross-sectional view for illustrating a process of forming a groove in a sixth embodiment.

FIG. 29 is a cross-sectional view for illustrating a joining process in the sixth embodiment.

FIG. 30 is a cross-sectional view for illustrating a process of forming a groove in a seventh embodiment.

FIG. 31 is a cross-sectional view for illustrating a joining process in the seventh embodiment.

### DETAILED DESCRIPTION OF INVENTION

### First Embodiment

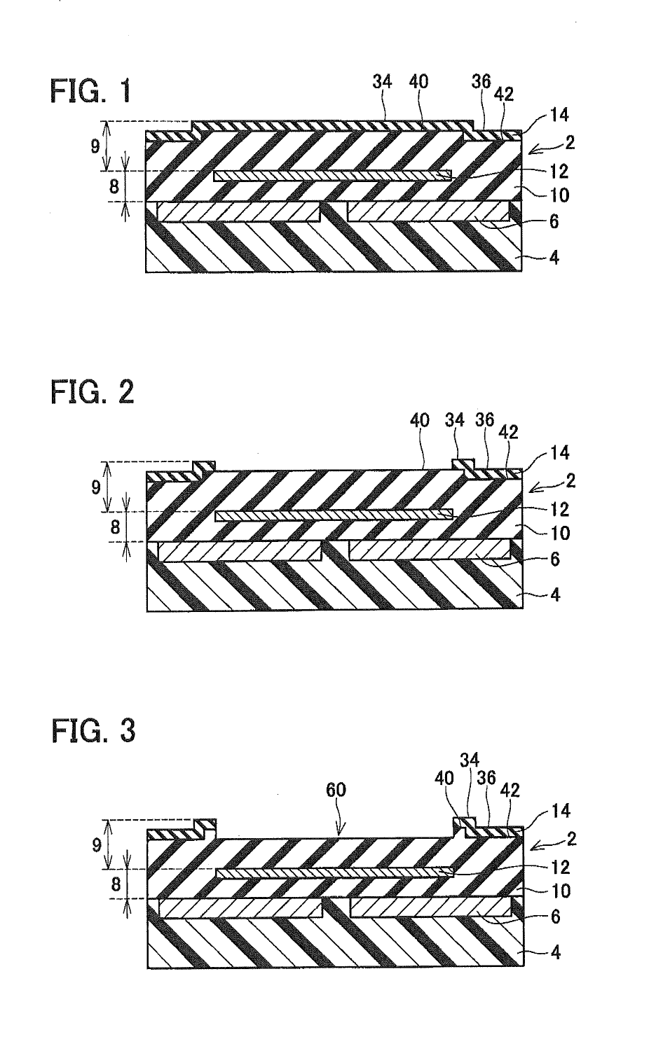

A method for producing a semiconductor device in a first embodiment will be described with reference to FIGS. 1 to 9.

### Opening Forming Process

First, as shown in FIG. 1, a CMOS (abbreviation of Complementary Metal-Oxide Semiconductor) wafer 2 is prepared. The CMOS wafer 2 comprises a bare wafer 4, a circuit 6, a silicon oxide film 10, a metal member 12 and a silicon nitride film 14. The bare wafer 4 is a substrate that is formed of silicon and the like. The bare wafer 4 is a plate-shaped member. The circuit 6 is located on the bare wafer 4. The circuit 6 is an electrical circuit such as a transistor circuit. The silicon oxide film 10 covers the bare wafer 4 and the circuit 6. The silicon oxide film 10 is used as an insulating material. The metal member 12 is located within the silicon oxide film 10. Although the illustration is omitted, within the silicon oxide film 10, in addition to the metal member 12, another metal member may be located. In this case, the metal member 12 would be located in the uppermost part (that is, the farthest part from the bare wafer 4) of a plurality of metal members. In the surface of the silicon oxide film 10, a step is formed. A first surface 40 is a part of the surface of the silicon oxide film 10 that is above the metal member 12 and is in the vicinity thereof. A second surface 42 is the part of the surface of the silicon oxide film 10 other than the first surface 40. The first surface 40 is in a position higher than the second surface 42. The silicon nitride film 14 covers the silicon oxide film 10 such that its thickness is substantially constant. The silicon nitride film 14 is used to enhance the humidity resistance of the CMOS wafer 2. A third surface 34 is a part of the silicon nitride film 14 that covers the first surface 40. A fourth surface 36 is a part that covers the second surface 42. The third surface 34 is in a position higher than the fourth surface 36. Although in the present embodiment, the films of two layers consisting of the silicon oxide film 10 and the silicon nitride film 14 are formed, in a variation, these films may be alternately deposited in layers to form films of three or more layers. However, the uppermost layer is preferably the silicon nitride film A part of the silicon oxide film 10 that is located on the sides of and below the metal member 12 is referred to as an interlayer insulating film 8. The interlayer insulating film 8 is formed to insulate the metal member 12 (and the other metal members) included in the interlayer insulating film. The part of the silicon oxide film 10 other than the interlayer insulating film 8 (that is, the part located above the metal member) and the silicon nitride film 14 are referred to as a passivation film 9. The passivation film 9 is formed to protect the CMOS wafer 2. In order to acquire the long-term reliability of the CMOS wafer 2, the passivation film 9 needs to be formed so as to have a constant thickness or more. An opening 60 and a conduction hole 70 that will be described later are formed in the passivation film 9.

Then, as shown in FIG. 2, a part (that is, a part of the third surface 34) of the silicon nitride film 14 that is located above the metal member 12 is removed by dry etching using trifluoromethane. In this way, a part of the first surface 40 is exposed. The exposed first surface 40 is located lower than the surface (that is, the remaining third surface 34) on the outside thereof.

Then, as shown in FIG. 3, dry etching using tetrafluoromethane and trifluoromethane is performed on the exposed part (that is, a part of the first surface 40) of the silicon oxide film 10. In this way, the non-penetrating opening 60 is formed. Consequently, a step is formed in the surface within and outside the opening 60.

### Conduction Hole Forming Process

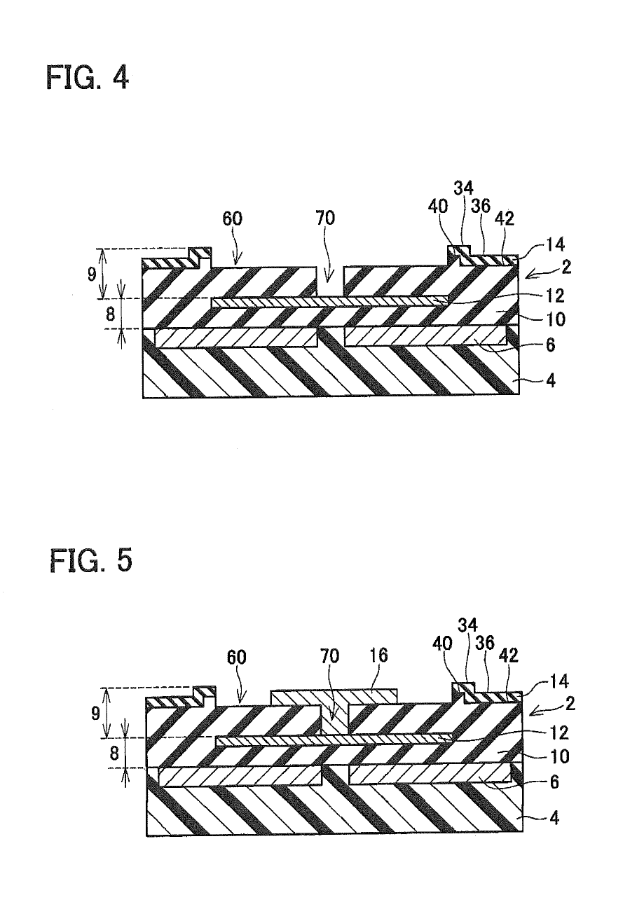

Then, as shown in FIG. 4, dry etching using tetrafluoromethane and trifluoromethane is performed on a part of the silicon oxide film 10 in the inside of the opening 60. In this way, the conduction hole 70 communicating with the metal member 12 is formed.

### Arranging Process

Then, as shown in FIG. 5, a joining material 16 that is formed in an appropriate shape is arranged within the conduction hole 70 and at a specific part of the inside of the opening 60. Here, the specific part refers to a part on the inside of the opening 60 around the conduction hole 70, and does not refer to the entire inside of the opening 60. This is because if the joining material 16 is arranged on the entire inside of the opening 60, in the joining that will be described later, it is likely that the joining material flows to the outside of the opening 60. The joining material 16 is a conductive material such as metal or silicon. The joining material 16 may be an alloy material that becomes an alloy when it is joined to a joining material 26 which will be described later.

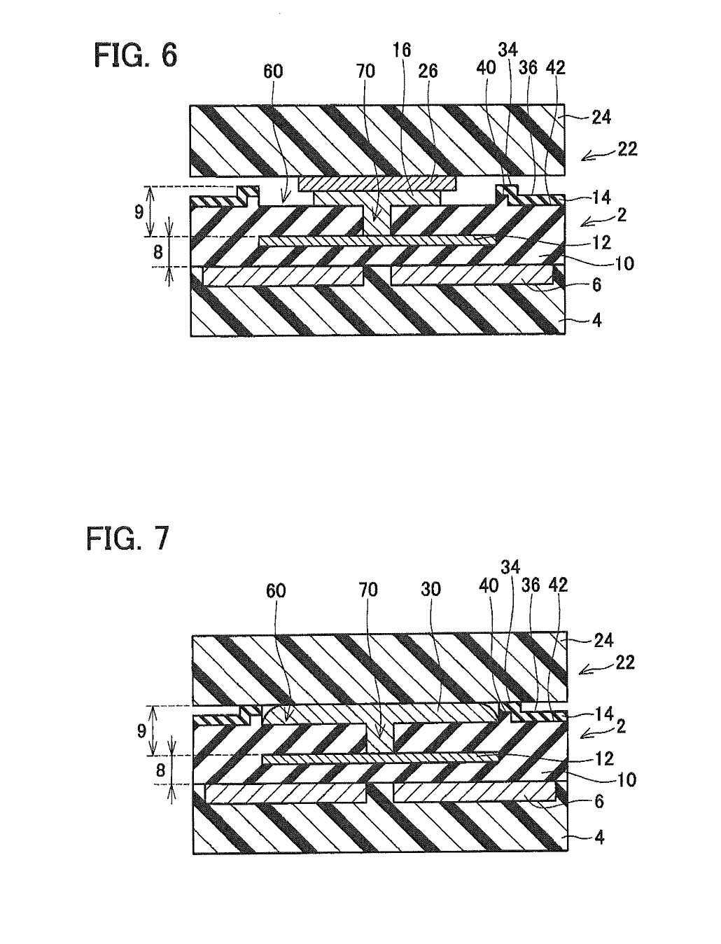

Then, as shown in FIG. 6, a MEMS (abbreviation of Micro Electro Mechanical Systems) wafer 22 is prepared. The MEMS wafer 22 comprises a bare wafer 24 and an unillustrated circuit. The MEMS wafer 22 differs from the CMOS wafer 2 in that it does not comprise a silicon oxide film and a silicon nitride film. Then, the joining material 26 that is formed in an appropriate shape is arranged on the bare wafer 24. As with the joining material 16, the joining material 26 is formed of metal, silicon, an alloy material or the like.

### Joining Process

Then, as shown in FIG. 7, the joining materials 16 and 26 are joined. In this way, the joining materials 16 and 26 are formed as a joining material 30. As the joining method, any one of thermal compression, eutectic bonding, brazing, soldering and the like may be used. In the joining, the dissolved joining material 30 is pressed in a vertical direction, and is thereby spread onto the opening 60. However, as described above, since the step is formed between the surface within and outside the opening 60, the spread joining material 30 is blocked by the step, and is thereby prevented from flowing to the outside of the opening 60. Since the joining material 30 spread to the inside of the opening 60 covers the exposed silicon oxide film 10 (that is, the opening 60), the humidity resistance of the CMOS wafer 2 can be enhanced.

The surface of the bare wafer 24 in the MEMS wafer 22 makes contact with the uppermost part (that is, the remaining third surface 34) of the CMOS wafer 2. In this way, an appropriate distance is acquired between the CMOS wafer 2 and the MEMS wafer 22, and thus it is possible to reliably form a stable junction (that is, a junction whose size and shape are constant). As a method for forming a stable junction other than the configuration in the present embodiment, a configuration in which the thickness of the joining materials 16 and 26 is increased can also be considered. However, in the configuration described above, the amount of joining material 30 is significantly increased. Hence, in the joining process, the following problems occur: warpage or bending occurs, the joining material 30 is easily spread, so it is difficult to make an adjustment such that the size and height of the joining part are appropriate and the like.

With the above steps, it is possible to produce a semiconductor device.

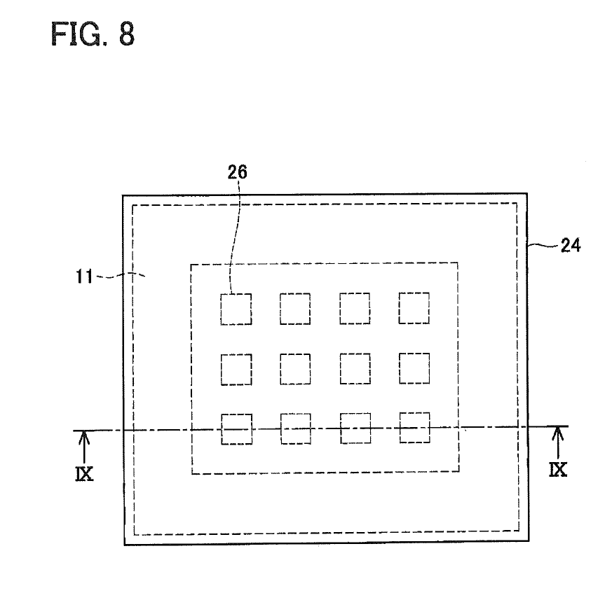

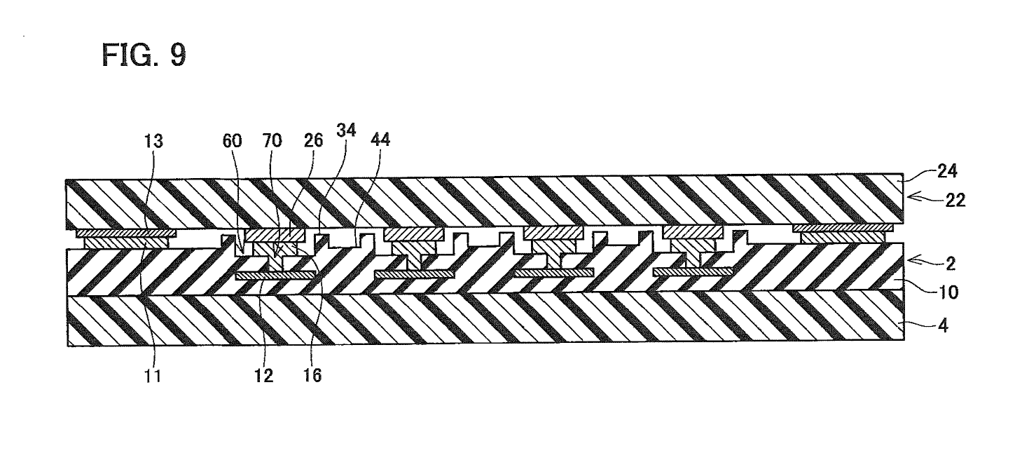

FIG. 8 schematically shows a top view of the semiconductor device 1 when 12 junctions are formed between the CMOS wafer 2 and the MEMS wafer 22. FIG. 9 shows a cross-sectional view of the semiconductor device 1 sectioned along dashed line IX of FIG. 8. As described above, a plurality of junctions may be formed. In the present embodiment, even when a plurality of junctions is formed, the joining parts can be prevented from contacting with each other since the joining material 30 is unlikely to be spread. In particular, when the space between the joining parts is narrow, the effect of preventing the joining parts from contacting with each other is useful.

Sealing materials 11 and 13 are arranged on the CMOS wafer 2 and the MEMS wafer 22, respectively. The sealing materials 11 and 13 are formed around the entire circumference of the 12 joining parts. The sealing material 11 is formed on the unillustrated silicon nitride film 14. That is, in order to arrange the sealing material 11, it is not necessary to remove the silicon oxide film 10 and the silicon nitride film 14. The sealing material 13 is formed on the bare wafer 24. As with the joining material, the sealing materials 11 and 13 may be formed of metal, silicon, an alloy material or the like. The sealing materials 11 and 13 may also be formed of a material that is not conductive. The sealing materials 11 and 13 are joined, and thus the space where the 12 joining parts are located is hermetically sealed, with the result that the humidity resistance can be further enhanced.

### Effect of the First Embodiment

According to the present embodiment, in the forming of the opening, the opening 60 is formed in the CMOS wafer 2, and thus the step is formed between the surface within and outside the opening 60. Hence, in the joining, the joining material 30 is unlikely to flow to the outside of the opening 60. That is, the spreading of the joining material 30 in the horizontal direction can be reduced.

### Second Embodiment

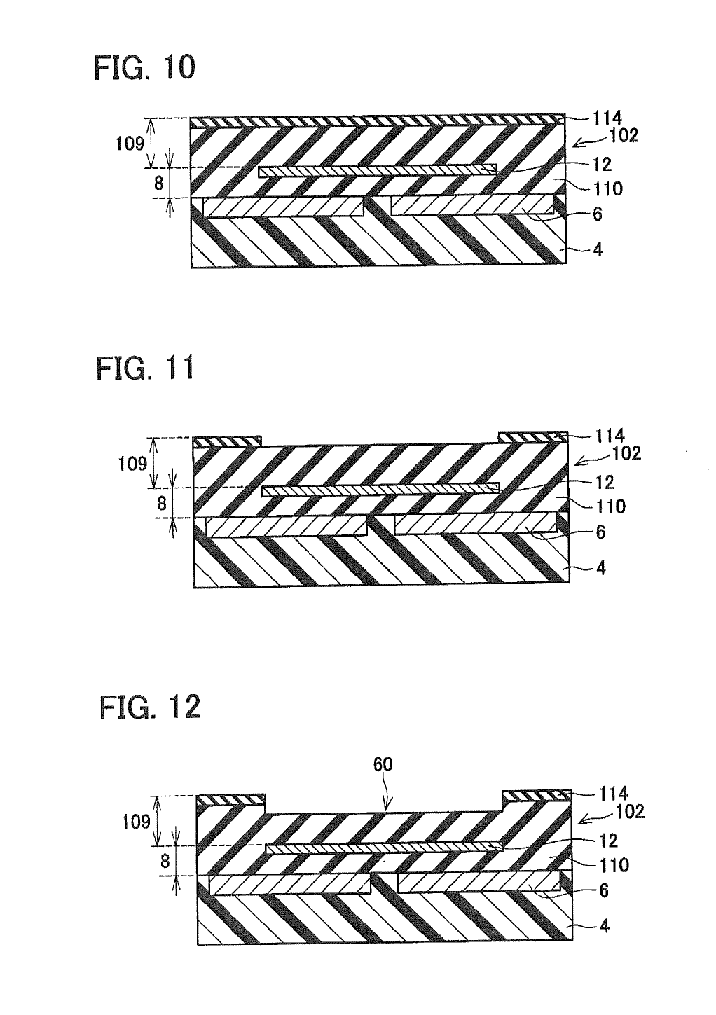

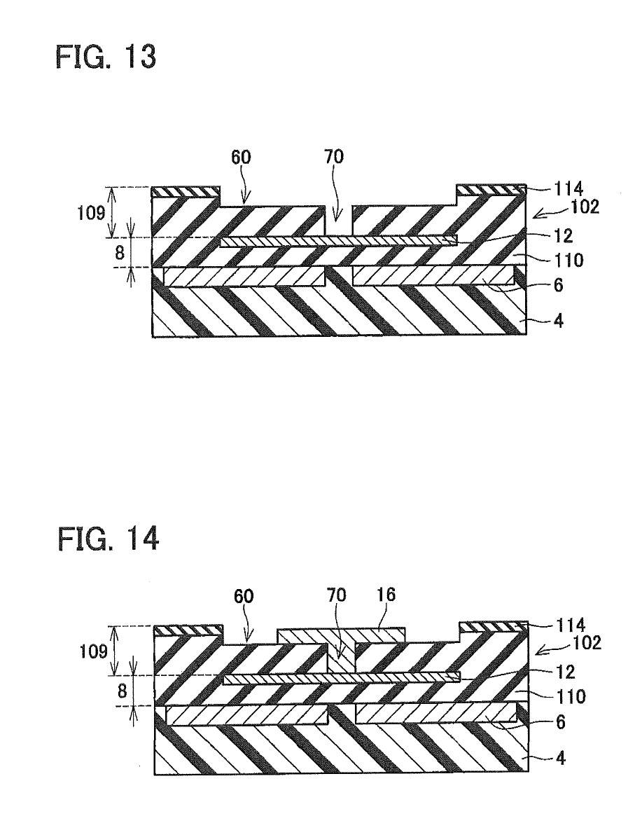

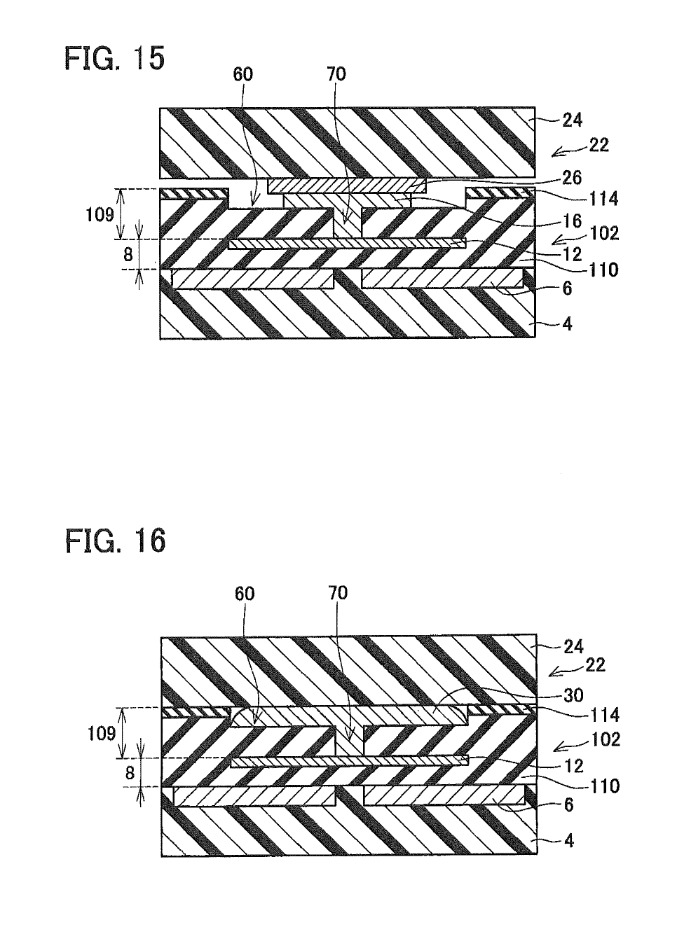

A method for producing a semiconductor device in a second embodiment will be described with reference to FIGS. 10 to 16 with attention focused mainly on points different from the first embodiment.

As shown in FIG. 10, in the initial state, in a CMOS wafer 102, the surfaces of a silicon oxide film 110 and a silicon nitride film 114 are located at constant heights, and no step is formed. That is, the shape of a passivation film 109 is different from that of the passivation film 9 in the first embodiment.

FIGS. 11 to 16 are the same as FIGS. 2 to 7 in the first embodiment. In FIG. 16, the surface of the bare wafer 24 in the MEMS wafer 22 contacts with the entire remaining silicon nitride film 114 in the CMOS wafer 102.

### Effect of the Second Embodiment

Even in the present embodiment, it is possible to obtain the same effect as in the first embodiment.

### Third Embodiment

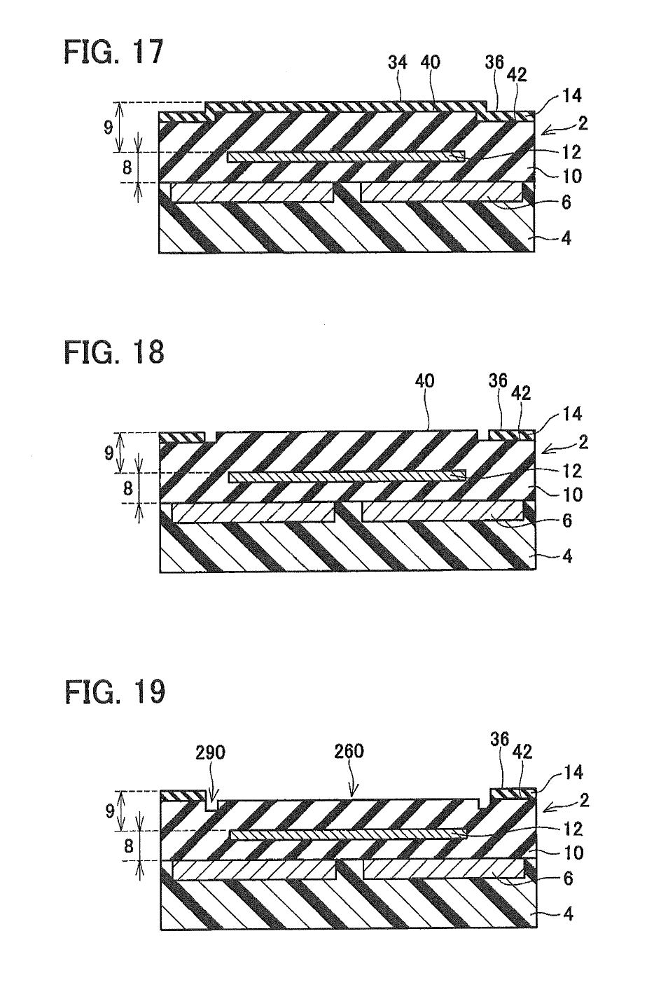

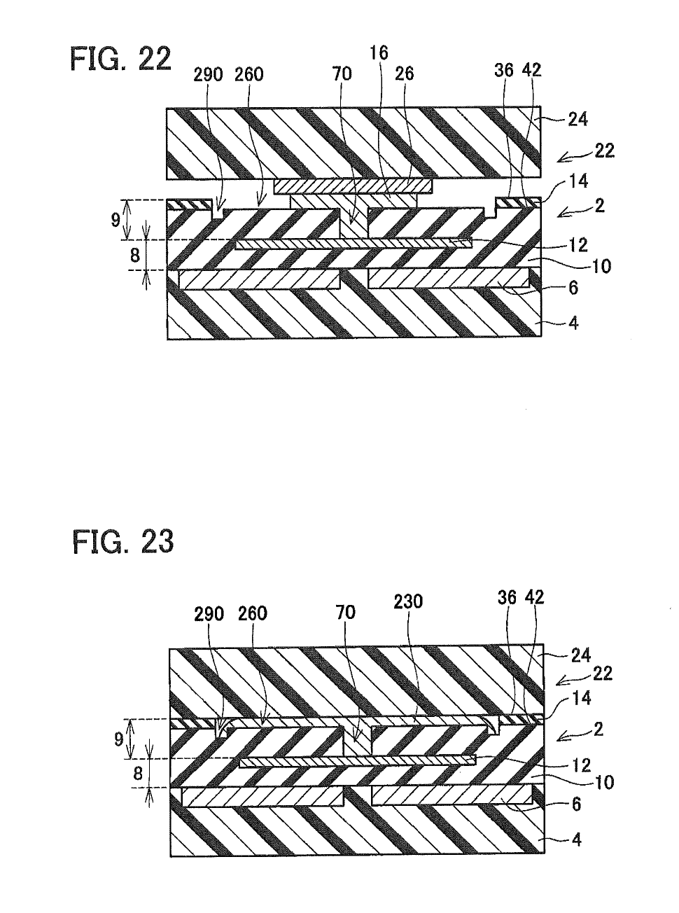

A method for producing a semiconductor device in a third embodiment will be described with reference to FIGS. 17 to 23 with attention focused mainly on points different from the first embodiment.

FIG. 17 is the same as FIG. 1 in the first embodiment.

As shown in FIG. 18, dry etching is performed on a wider area of the silicon nitride film 14 than in FIG. 2 of the first embodiment. Specifically, dry etching is performed on the entire third surface 34 and a part of the fourth surface 36 in the vicinity of the third surface 34. In this way, the entire first surface 40 and a part of the second surface 42 in the vicinity of the first surface 40 are exposed.

As shown in FIG. 19, similar to FIG. 3 of the first embodiment, dry etching is performed on the exposed part (that is, the entire first surface 40 and the part of the second surface 42 in the vicinity of the first surface 40). That is, in the entire area on which dry etching is performed, a non-penetrating opening 260 is formed, and in a part of the second surface 42 in the vicinity of the first surface 40, a groove 290 is formed. In other words, the groove 290 is in the inside of the opening 260, and is formed so as to contact with the outer edge of the opening 260. The groove 290 is also formed so as to surround the entre circumference of parts where the joining material 16 is arranged, which will be described later.

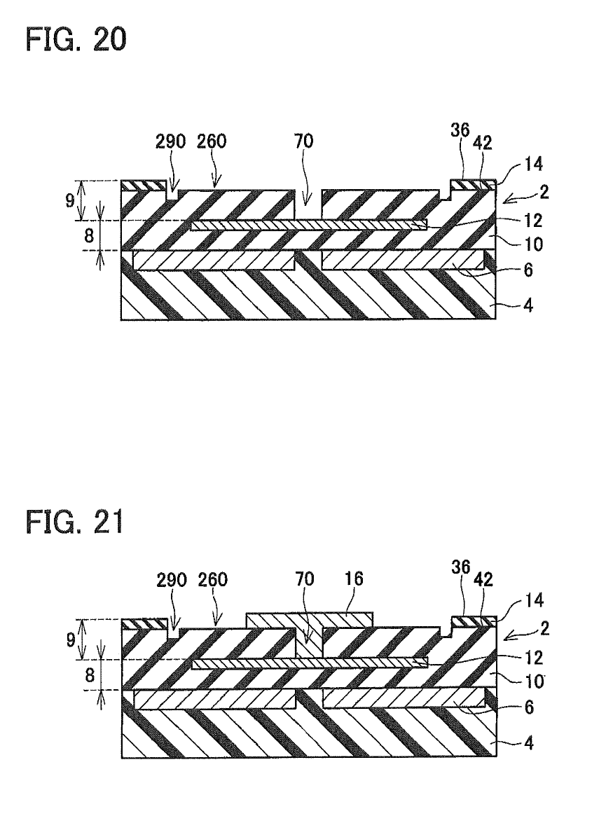

FIGS. 20 to 22 are the same as FIGS. 4 to 6 in the first embodiment.

As shown in FIG. 23, the joining materials 16 and 26 are joined. In this way, the joining materials 16 and 26 are formed as a joining material 230. Similar to FIG. 7 of the first embodiment, the joining material 230 is spread onto the opening 260. However, the spread joining material 230 flows into the groove 290. Since a step is formed between the surface of the inside (that is, the inside of the opening 260) of the groove 290 and the surface of the outside of the opening 260, the spread joining material 230 is blocked by the step, and is thereby prevented from flowing to the outside of the opening 260. The surface of the bare wafer 24 in the MEMS wafer 22 contacts with the uppermost part (that is, the remaining part of the silicon nitride film 14 that is not removed) of the CMOS wafer 2.

### Effect of the Third Embodiment

Even in the present embodiment, the same effect as in the first embodiment is obtained. In the present embodiment, furthermore, since the groove 290 is formed in the CMOS wafer 2, the flow of the joining material 230 to the outside of the opening 260 can be further reduced.

### Fourth Embodiment

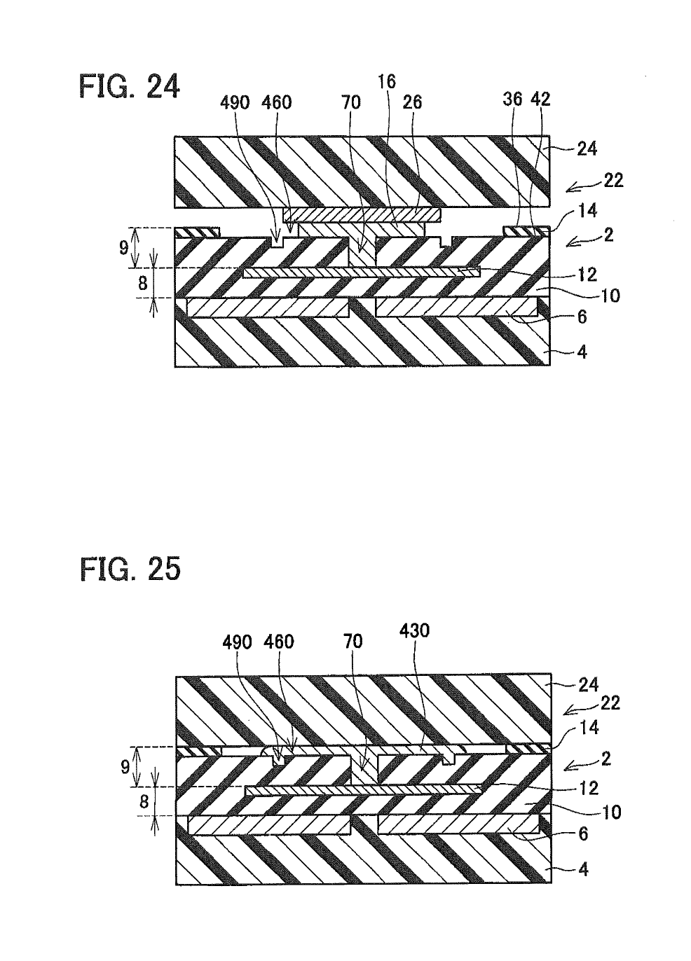

A method for producing a semiconductor device in a fourth embodiment will be described with reference to FIGS. 24 and 25 with attention focused mainly on points different from the third embodiment. In the subsequent embodiments, the forming of the opening, the forming of the conduction hole, the arranging and the forming of the groove are not illustrated.

### Joining Process

As shown in FIG. 24, in the present embodiment, as compared with the third embodiment, a groove 490 is formed further inward of an opening 460.

As shown in FIG. 25, the joining materials 16 and 26 are joined. In this way, the joining materials 16 and 26 are formed as a joining material 430. The spread joining material 430 flows into the groove 490. Since a step is formed between the surface of the inside of the groove 490 and the surface of the inside of the opening 460 but outside the groove 490, the spread joining material 430 is blocked by the step, and is thereby unlikely to flow to the outside of the groove 490. Further, since another step is formed in the surface within and outside the opening 260, even if the joining material 430 flows to the outside of the groove 490, the joining material 430 does not flow to the outside of the opening 260.

### Effect of the Fourth Embodiment

Even in the present embodiment, the same effect as in the third embodiment is obtained.

### Fifth Embodiment

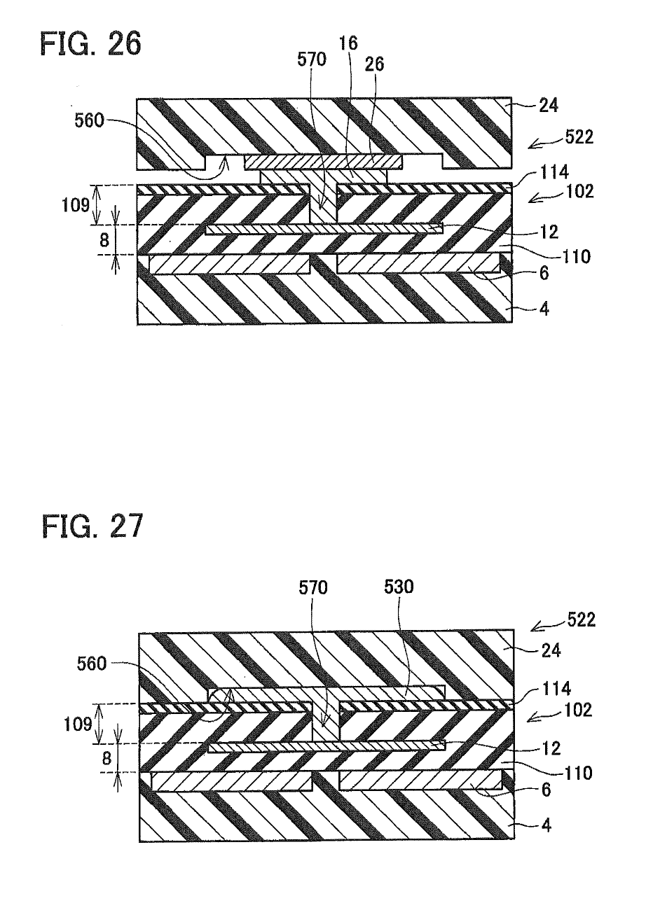

A method for producing a semiconductor device in a fifth embodiment will be described with reference to FIGS. 26 and 27 with attention focused mainly on points different from the second embodiment.

As shown in FIG. 26, in the present embodiment, an opening 560 is formed in a MEMS wafer 522. Although it is not illustrated, in the forming of the opening, the opening 560 is formed by cutting the bare wafer 24. On the other hand, although in a CMOS wafer 102, a conduction hole 570 is formed, an opening is not formed. That is, only the part of the silicon oxide film 110 and the silicon nitride film 114 where the conduction hole 570 is located is removed. The joining material 16 is arranged in the conduction hole 570 and the part of the silicon nitride film 514 in the vicinity of the conduction hole 570. The joining material 26 is arranged in the inside of the opening 560.

As shown in FIG. 27, the joining materials 16 and 26 are joined. In this way, the joining materials 16 and 26 are formed as a joining material 530. At the time of the joining, the dissolved joining material 530 is pressed in a vertical direction, and is thereby spread onto the opening 560. However, since a step is formed between the surface within and outside the opening 560, the spread joining material 530 is blocked by the step, and does not flow to the outside of the opening 560. The uppermost part (that is, the part of the outside of the opening 560) of the bare wafer 24 in the MEMS wafer 522 makes contact with the remaining silicon nitride film 114 in the CMOS wafer 2.

### Effect of the Fifth Embodiment

According to the present embodiment, in the forming of the opening, the opening 560 is formed in the MEMS wafer 522, and thus the steps are formed in the surface within and outside the opening 560. Hence, in the joining, the joining material 530 is unlikely to flow to the outside of the opening 560. That is, the spreading of the joining material 530 in the horizontal direction can be reduced.

Furthermore, in the present embodiment, the area of the silicon nitride film 114 that is removed is narrow. In this area, the joining material 16 is arranged. Hence, as compared with the first to fourth embodiments, the humidity resistance of the CMOS wafer 102 can be further enhanced.

### Sixth Embodiment

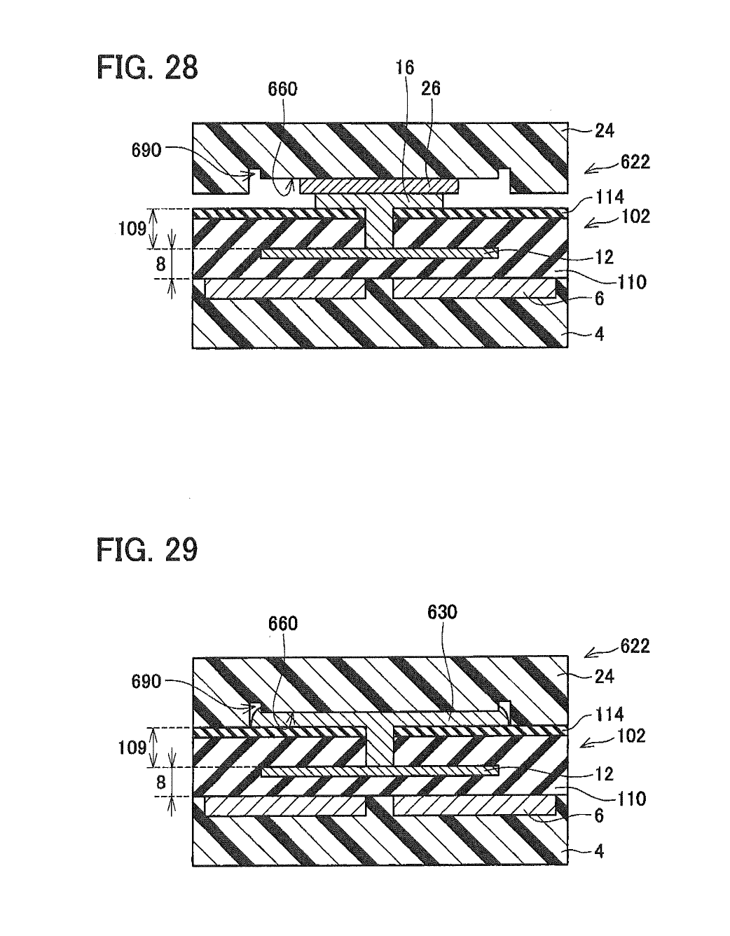

A method for producing a semiconductor device in a sixth embodiment will be described with reference to FIGS. 28 and 29 with attention focused mainly on points different from the fifth embodiment.

As shown in FIG. 28, as in FIG. 26 of the fifth embodiment, an opening 660 is formed in a MEMS wafer 622. In the present embodiment, furthermore, a groove 690 is in the inside of the opening 660 and is formed so as to contact with the outer edge of the opening 660.

As shown in FIG. 29, the joining materials 16 and 26 are joined. In this way, the joining materials 16 and 26 are formed as a joining material 630. As in FIG. 27 of the fifth embodiment, the joining material 630 is spread onto the opening 660. However, the spread joining material 630 flows into the groove 690. Since a step is formed between the surface of the inside (that is, the inside of the opening 660) of the groove 690 and the surface of the outside of the opening 660, the spread joining material 630 is blocked by the step, and does not flow to the outside of the opening 660.

Even in the present embodiment, the same effect as in the fifth embodiment is obtained. In the present embodiment, furthermore, since the groove 690 is formed in the MEMS wafer 622, the flow of the joining material 630 to the outside of the opening 660 can be further reduced.

### Seventh Embodiment

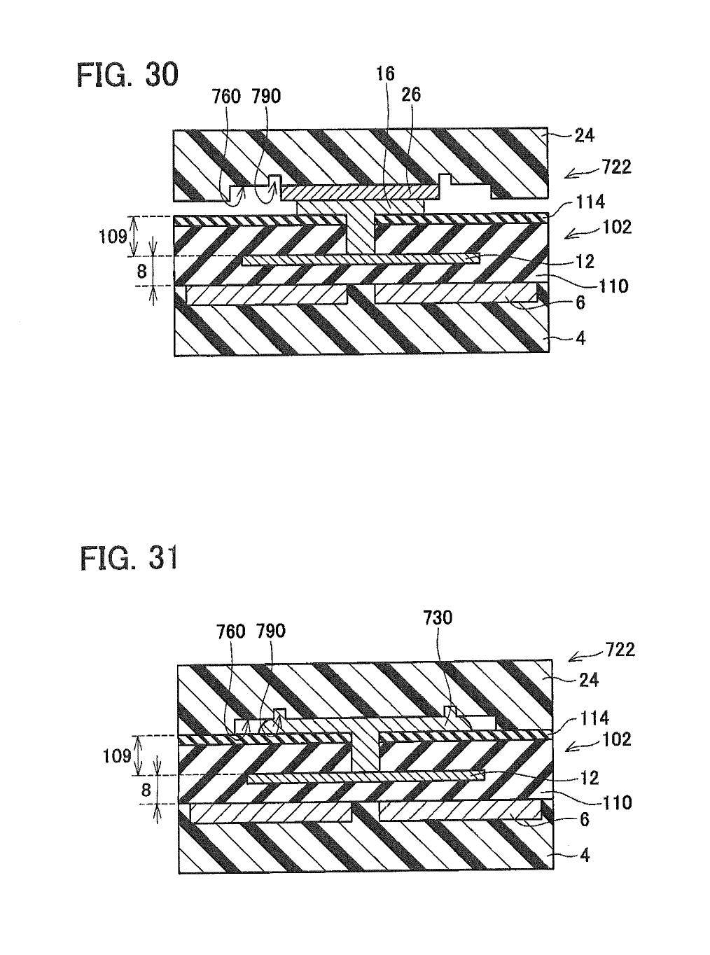

A method for producing a semiconductor device in a seventh embodiment will be described with reference to FIGS. 30 and 31 with attention focused mainly on points different from the sixth embodiment.

As shown in FIG. 30, the present embodiment differs from the sixth embodiment in that a groove 790 is formed further inward of an opening 760.

As shown in FIG. 31, the joining materials 16 and 26 are joined. In this way, the joining materials 16 and 26 are formed as a joining material 730. The spread joining material 730 flows into the groove 790. Since a step is formed between the surface of the inside of the groove 790 and in the surface of the inside of the opening 760 but outside the groove 790, the spread joining material 730 is blocked by the step, and is thereby unlikely to flow to the outside of the groove 790. Since another step is formed between the surface within and outside the opening 760, even if the joining material 730 flows beyond the groove 790, the joining material 730 does not flow to the outside of the opening 760.

### Effect of the Seventh Embodiment

Even in the present embodiment, the same effect as in the sixth embodiment can be obtained.

### Correlation Relationship

The MEMS wafers 22, 522 and 622 are an example of “another semiconductor wafer.” The parts of the openings 60, 260 and 460 where the joining material 16 is arranged in FIGS. 5, 6, 14, 15, 21, 22 and 24 and the part of the silicon nitride film 114 where the joining material 16 is arranged in FIGS. 26, 28 and 30 are an example of a “first part.” The parts of the MEMS wafers 22, 522, 622 and 722 where the joining material 26 is arranged in FIGS. 6, 15, 24, 26, 28 and 30 are an example of a “second part.”

### Variation 1

In FIG. 3 of the first embodiment, the opening 60 is formed in the CMOS wafer 2, and in FIG. 26 of the fifth embodiment, the opening 560 is formed in the MEMS wafer 22. That is, the opening is formed in only one of the CMOS wafer and the MEMS wafer. In a variation, the opening may be formed both in the CMOS wafer and in the MEMS wafer. That is, the opening may be formed in the area over the inside and the outside both of the “first part” and of the “second part.”

### Variation 2

In FIG. 19 of the third embodiment, the groove 290 is formed in the CMOS wafer 2, and in FIG. 28 of the sixth embodiment, the groove 690 is formed in the MEMS wafer 622. In other words, the groove is formed in only one (that is, the wafer where the opening is formed) of the CMOS wafer and the MEMS wafer. However, the groove may be formed in only the other (that is, the wafer where the opening is not formed) of the CMOS wafer and in the MEMS wafer. In this case, the groove is formed so as to surround the entire circumference of the parts where the joining materials are arranged in the arranging. The groove may be formed both in the CMOS wafer and in the MEMS wafer.

### Variation 3

Instead of the MEMS wafer in each of the embodiments, for example, another type of wafer such as a CMOS wafer or a BICMOS (the abbreviation of Bipolar Complementary Metal-Oxide Semiconductor) wafer may be used. That is, “another semiconductor wafer” may be any type of semiconductor wafer.

### Variation 4

In each of the embodiments, the two semiconductor wafers are joined, and thus the semiconductor device is produced. In a variation, the steps of the embodiment are repeated to join three or more semiconductor wafers, and thus the semiconductor device may be produced.

### Variation 5

Although in each of the embodiments, the silicon oxide film and the silicon nitride film are not formed in the surface of the MEMS wafer, in a variation, they may be formed. In the present variation, when the opening and the groove are formed in the MEMS wafer (see the fifth to seventh embodiments), the parts of the silicon oxide film and the silicon nitride film where the opening and the groove are located are removed.

Some of the features of the embodiments described above will be mentioned. Each of the features mentioned here is independently effective.

### Feature 1

In the method of producing the semiconductor device, the forming of the opening may include forming the opening in the area including the first part and the outer peripheral part of the first part.

### Feature 2

The method of producing the semiconductor device may further include forming a groove surrounding an entire circumference of at least one of the first part and the second part, the groove being located outside at least one of the first part and the second part and inside the opening. The forming of the groove may be performed before the joining. In this configuration, in the joining, the first joining material and the second joining material that reach the groove flow into the groove. Hence, the spreading of the first joining material and the second joining material in the horizontal direction can be reduced.

### Feature 3

The semiconductor device may comprise the opening on the first surface, the opening terminating within and not penetrating through the complementary metal-oxide semiconductor wafer.

### Feature 4

The semiconductor device may further comprise a groove surrounding an entire circumference of a specific region inside the opening.

What is claimed is:

1. A method for producing a semiconductor device that comprises a complementary metal-oxide semiconductor wafer and another semiconductor wafer, the complementary metal-oxide semiconductor wafer including a protective coating, the method comprising:
forming an opening in an area of at least one of the complementary metal-oxide semiconductor wafer that includes a first part and the other semiconductor wafer that includes a second part, the opening terminating within the area and not penetrating through the area, the area including corresponding one of the first part and the second part and an outer peripheral part of the corresponding one of the first part and the second part, the first part including a part of a surface of the complementary metal-oxide semiconductor wafer on which the protective coating is located and a part of the complementary metal-oxide semiconductor wafer continuing inward from the part of the surface, the second part including a part of a surface of the other semiconductor wafer and a part of the other semiconductor wafer continuing inward from the part of the surface;
forming a conduction hole within the first part, the conduction hole communicating with a metallic material in the complementary metal-oxide semiconductor wafer;
arranging a first joining material inside the conduction hole and on the first part, and a second joining material on the second part; and
joining the arranged first joining material and the arranged second joining material.

2. The method as in claim 1, wherein
the forming of the opening includes forming the opening in the area including the first part and the outer peripheral part of the first part.

3. The method as in claim 1, further comprising:
forming a groove surrounding an entire circumference of the at least one of the first part and the second part, the groove being located outside the at least one of the first part and the second part and inside the opening,
wherein the forming of the groove is performed before the joining.

4. A semiconductor device comprising:
a complementary metal-oxide semiconductor wafer; and
another semiconductor wafer,
wherein the complementary metal-oxide semiconductor wafer comprises:
a protective coating located on a surface of the complementary metal-oxide semiconductor wafer;
a metallic material located in the complementary metal-oxide semiconductor wafer;
a conduction hole communicating with the metallic material from a first surface being a surface on which the protective coating is located; and
a first joining material located in the conduction hole and on the first surface,
the other semiconductor wafer comprises a second joining material located on a second surface of the other semiconductor wafer and joined to the first joining material, and
the semiconductor device comprises an opening on at least one of the first surface of the complementary metal-oxide semiconductor and the second surface of the other semiconductor, the opening terminating within and not penetrating through the corresponding one of the complementary metal-oxide semiconductor wafer and the other semiconductor wafer,
wherein the first joining material and the second joining material fill at least a part of the opening is located on the at least one of the first surface and the second surface.

5. The semiconductor device as in claim 4, comprising the opening on the first surface, the opening terminating within and not penetrating through the complementary metal-oxide semiconductor wafer.

6. The semiconductor device as in claim 4, further comprising:
a groove surrounding an entire circumference of a specific region inside the opening.
